(19) United States
(12) Patent Application Publication
(10) Pub. No.: US 2020/0227600 A1
(43) Pub. Date: Jul. 16, 2020

(54) LED LIGHT SOURCE SUBSTRATE, LIGHTING DEVICE, AND METHOD OF PRODUCING LED LIGHT SOURCE SUBSTRATE

(71) Applicant: SHARP KABUSHIKI KAISHA, Sakai City (JP)

(72) Inventors: HISASHI WATANABE, Sakai City (JP); HIROTOSHI YASUNAGA, Sakai City (JP); YOUZOU KYOUKANE, Sakai City (JP); TAKESHI MASUDA, Sakai City (JP)

(21) Appl. No.: 16/732,716

(22) Filed: Jan. 2, 2020

Related U.S. Application Data
(60) Provisional application No. 62/792,161, filed on Jan. 14, 2019.

(51) Int. Cl. H01L 33/54; H01L 25/075; H01L 33/62; G02F 1/13357

(52) U.S. Cl. CPC H01L 33/54; H01L 25/0753; H01L 33/62; H01L 2933/0066; H01L 2933/0091; H01L 2933/005; G02F 1/133603

(57) ABSTRACT

An LED light source substrate includes a circuit board, LED bare chips, and a high refractive index layer. A wiring circuit is formed on the circuit board. The LED bare chips are mounted on the circuit board. The high refractive index layer is made of a material having light transmissivity and a refractive index higher than 1. The high refractive index layer is disposed astride the LED bare chips to embed the LED bare chips. The high refractive index layer has convex portions protruding to an opposite side to the circuit board at positions at which the LED bare chips are embedded.

### CROSS REFERENCE TO RELATED APPLICATION

This application claims priority from U.S. Provisional Patent Application No. 62/792,161 filed on Jan. 14, 2019. The entire contents of the priority application are incorporated herein by reference.

### TECHNICAL FIELD

The technology disclosed by this specification relates to an LED light source substrate, a lighting device, and a method of producing LED source substrate.

### BACKGROUND

As various types of light sources of lighting devices provided for display devices, light sources using light-emitting diodes (LEDs) are known. Surface-mount LEDs have been used for directly-below lighting device provided with a light source directly below a display panel. Each surface-mount LED is obtained by mounting an LED bare chip in a resin package and sealing the LED bare chip with a sealing resin. In recent years, in order to satisfy demands for thinner display devices, studies have been made on a method of mounting many LEDs side by side with a small pitch in a directly-below lighting device. In this case, in order to prevent an increase in cost due to an increase in the number of LEDs used, the price per LED is preferably reduced by using LED bare chips directly mounted on a circuit board instead of the above surface-mount LEDs. For example, Japanese Unexamined Patent Application Publication No. 2007-53352 discloses a light-emitting diode light source having light-emitting diode elements mounted on the same substrate. This light-emitting diode light source is designed to achieve uniform luminance and the like by covering light-emitting diode elements with a mold resin.

The ratio of light exiting from a given object (to be sometimes referred to as a light exiting ratio hereinafter) decreases with an increase in difference between the refractive index of the object and the refractive index of a material provided around the object. This is because as the refractive index difference increases, light is reflected at the interface and confined more inside the object. For example, an LED bare chip, which is not sealed with a resin, is generally made of a high refractive index material, and is formed by, for example, providing GaN having a refractive index of about 2.3 or AlInGap having a refractive index of about 3.3 on a sapphire substrate having a refractive index of about 1.75. When such an LED bare chip is caused to emit light in air having a refractive index of 1, the light exiting ratio from the LED bare chip greatly decreases, and the ratio of light effectively used to the light emitted from the light source (to be sometimes referred to as a light use efficiency hereinafter) decreases. This poses a problem that a lighting device or display device using such LED bare chips cannot obtain sufficient luminance.

In the light-emitting diode light source, if the mold resin in which the LED bare chips are embedded has a higher refractive index than air (refractive index of 1), the light exiting ratio from each LED bare chip becomes higher than when the LED bare chip is caused to emit light in air. However, when light propagating in the mold resin (and the resin film stacked on the mold resin) exits into air, the amount of exiting light is reduced by interface reflection, resulting in a decrease in light use efficiency. A relatively large amount of light from a light-emitting diode having a flat surface made of a mold resin or the like is reflected by the interface between the mold resin or the like and air. Accordingly, the light use efficiency decreases. It is expected that forming a surface made of a mold resin or the like an uneven pattern will increase the light use efficiency as compared with a flat surface. However, if the surface is only randomly formed in uneven pattern irrelevantly of the arrangement position of each LED bare chip, the effect of improving the light exiting ratio from the mold resin or the like is only limited. That is, there is still room for improvement. In addition, in a manufacturing process of a light-emitting diode light source, it is necessary to form an uneven pattern on a surface made of mold resin or the like or use a resin film having an uneven pattern. This may increase the complexity of the manufacturing process or the manufacturing cost.

### SUMMARY

This technology is completed in consideration of the above situation, and has as its object to provide an LED light source substrate enabling the formation of a lighting device with high light use efficiency by a simple method.

An LED light source substrate includes a circuit board on which a wring circuit is formed, LED bare chips mounted on he circuit board, and a high refractive index layer made of a material having light transmissivity and a refractive index higher than 1. The high refractive index layer is disposed astride the LED bare chips so as to embed the LED bare chips, and the high refractive index layer has a convex portions protruding to an opposite side to the circuit board at positions at which the LED bare chips are embedded. Note that in the above description, “embed” means to dispose the high refractive index layer so as to cover the side surfaces, the upper surface, and the like of the surface of each LED bare chip except for the surface connected to the circuit board.

A lighting device includes the LED light source substrate described above.

A method of producing an LED light source substrate includes: an LED bare chip mounting step of preparing an LED-mounted substrate by mounting LED bare chips on a circuit board on which wiring routes are formed; and an LED bare chip embedding step of providing a high refractive index layer on a mounting surface of the LED-mounted substrate astride the LED bare chips so as to embed the LED bare chips. The high refractive index layer is made of a material having light transmissivity and a refractive index higher than 1 and has convex portions protruding to an opposite side of each of the LED bare chips as a center to the circuit board.

This technology can obtain a lighting device using LEDs as light sources and having excellent light use efficiency.

### BRIEF DESCRIPTION OF THE DRAWINGS

FIG. 1 is a schematic view schematically showing a sectional arrangement of a display device according to the first embodiment.

FIG. 2 is a schematic view schematically showing a sectional arrangement of a portion near the LED bare chip embedded portion of an LED light source substrate according to the first embodiment.

FIG. 3A is a view for explaining as example of a step of providing a high refractive index layer.

FIG. 3B is a schematic view schematically showing a sectional arrangement of an LED light source substrate after being provided with the high refractive index layer.

FIG. 4A is a view for explaining outlines of optical paths in the LED light source substrate on which an LED bare chip is mounted in a bare state.

FIG. 4B is a view for explaining outlines of optical paths in an LED light source substrate on which the surfaces of an embedding layer and a base material layer are formed in a flat shape.

FIG. 5A is a schematic view schematically showing a sectional arrangement of a portion near an LED bare chip embedded portion of an LED light source substrate according to the second embodiment.

FIG. 5B is a view for explaining an example of a step of providing a high refractive index layer.

FIG. 6A is a schematic view schematically showing a sectional arrangement of a portion near an LED bare chip embedded portion of an LED light source substrate according to the third embodiment.

FIG. 6B is a view for explaining an example of a step of providing a high refractive index layer.

FIG. 7A is a schematic view schematically showing a sectional arrangement of a portion near an LED bare chip embedded portion of an LED light source substrate according to the fourth embodiment.

FIG. 7B is a view for explaining an example of step of providing a high refractive index layer.

FIG. 8 is a schematic view schematically showing a sectional arrangement of a portion near an LED bare chip embedded portion of an LED light source substrate according to the fifth embodiment.

### DETAILED DESCRIPTION

### First Embodiment

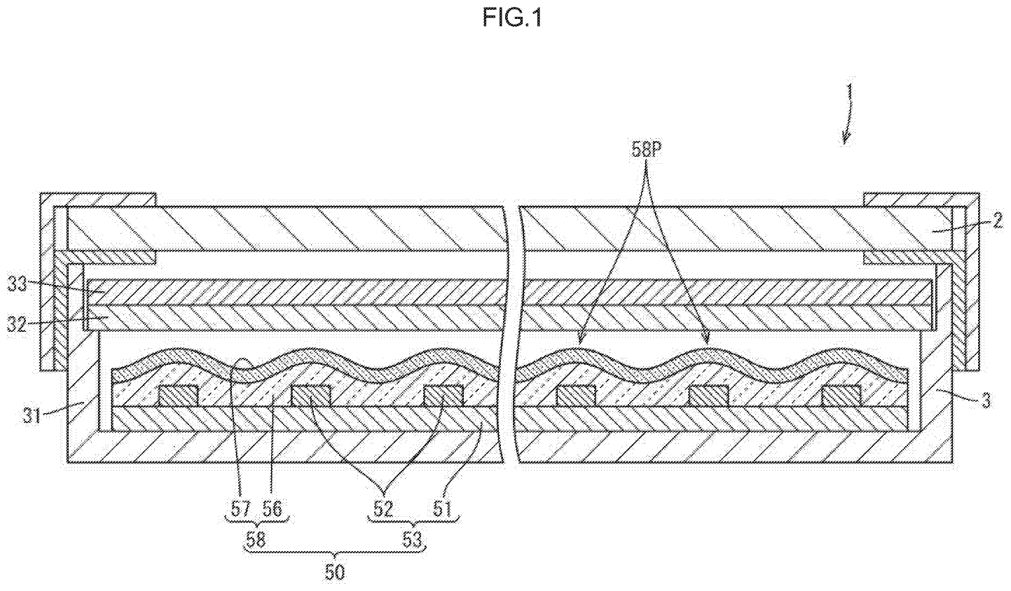

The first embodiment will be described with reference to FIGS. 1 to 4B. Note that in the following description, the upper side FIG. 1 and the like is regarded as the front side (the lower side is regarded as the rear side or the back surface side). When identical members are assigned with reference numerals, one member may be assigned with a reference numeral, and the remaining members may not be assigned with any reference numerals. In addition, the relative sizes and locations of the respective constituent members in each drawing are not necessarily accurate, and the measures of some members are changed in consideration of convenience in description.

This embodiment will exemplify a backlight device (an example of a lighting device) 3 used in a display device 1. As shown in FIG. 1, the display device 1 includes a liquid crystal panel 2 as a display panel and the backlight device 3 using LEDs as light sources. Among one pair of plate surfaces of the liquid crystal panel 2, the front-side plate surface serves as an image display surface. The backlight device 3 is fixed to the back surface of: the liquid crystal panel 2 through, for example, a frame and a bezel. The display device I can be widely applied to, for example, TV receivers, tablet terminals, car navigation equipment, smartphones, and head mount displays.

The liquid crystal panel 2 according to the first embodiment is a transmissive liquid crystal panel. Although a detailed description and description of the liquid crystal panel 2 will be omitted, for example, one pair of glass substrates are bonded to each other through a predetermined gap, and liquid crystal is sealed between the two glass substrates. Switching elements (for example, TFTs) connected to source lines and gate lines which are perpendicular to each other, pixel electrodes connected to the switching elements, an aligning film, and the like are provided on one glass substrate. A color filter having colored portions such as R (red, G (green), and B (blue) portions arranged in a predetermined array, a counter electrode, an aligning film, and the like are provided on the other glass substrate. Polarizing plates are arranged outside the two substrates. Driving of the liquid crystal panel 2 is controlled on the basis of electrical signals from an external signal source. The backlight device 3 supplies light in conjunction with control of the liquid crystal panel 2 to display a desired image on the image display surface of the liquid crystal panel 2.

The schematic arrangement of the backlight device 3 will be described with reference to FIG. 1. The backlight device 3 according to the first embodiment is a so-called directly-below backlight device having LED bare chips 52 as light sources arranged directly below the liquid crystal panel 2. The backlight device 3 includes a chassis 31 in a shallow substantially box-like shape having opening portion on the front side (beside the liquid crystal panel 2). As the chassis 31, a structure formed by metallic molding using a high refractive index resin, for example, a white polycarbonate resin can be used. The chassis 31 accommodates an LED light source substrate 50 to be described later.

A fluorescent sheet 32 and an optical sheet 33 are arranged on the front side (beside the liquid crystal panel 2) of the LED light source substrate 50 so as to cover the opening portion of the chassis 31. The fluorescent sheet 32 has a function of absorbing emission wavelengths from the LED bare chips 52 and emitting light of complementary colors to whiten exiting light. When, for example, the LED bare chip 52 that emits blue light is used, a sheet obtained by dispersing fluorescent materials that emit yellow light and green+red light into a resin or the like is used. More specifically, for example, a quantum dot enhancement film (QDEF), which is a light conversion sheet using quantum dots available from 3M Limited, can be used. When there is available another whitening method, such as using a combination of the LED bare chips 52 that emit red, green, and blue light, there is no need to use the fluorescent sheet 32. The optical sheet 33 has a function of converting light emitted from the LED bare chips 52 as point light sources into a uniform surface light source. As the optical sheet 33, a diffusion plate, a diffusion sheet, a prism sheet, a polarizing reflecting sheet, or the like is used as needed. A diffusion plate and a diffusion sheet are used to suppress light unevenness. More specifically, SUMIPEX (registered trademark) opal plate available from Sumitomo Chemical Co., Ltd, D114 available from TSUJIDEN Co., Ltd, or the like is used. A prism sheet and a polarizing reflecting sheet are used to improve luminance. For example, BEF (registered trademark) series and DBEF (registered trademark) series available from 3M Limited can be used. The fluorescent sheet 32 and the optical sheet are typically stacked in the following order from the back-surface side (beside the LED bare chip 52): the fluorescent sheet 32 and the optical sheet 33 (the diffusion sheet, prism sheet, or polarizing reflecting sheet). Light exiting from the LED light source substrate 50 (to be described later passes through the fluorescent sheet 32 and the optical sheet 33 and is applied as planar light with high uniformity to the liquid crystal panel 2 from the back-surface side.

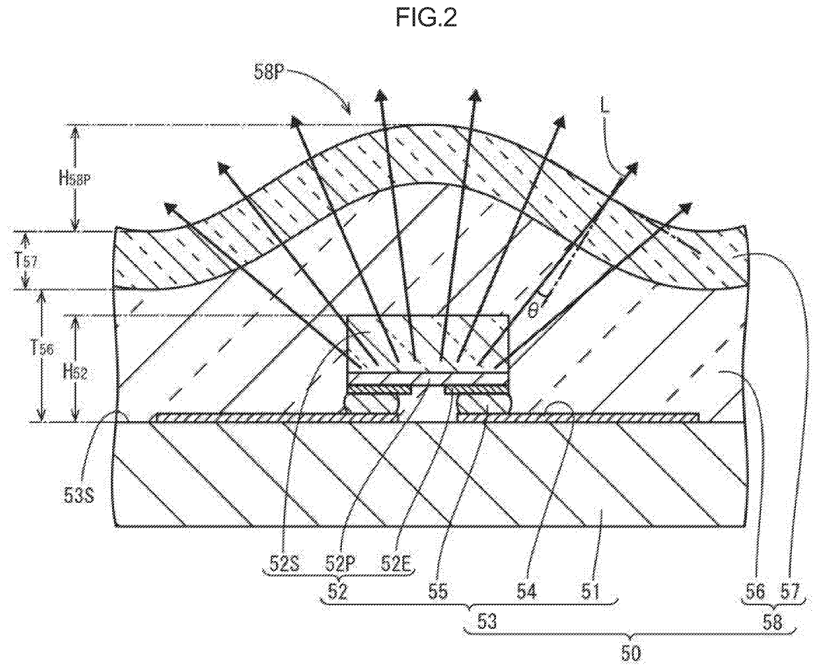

The LED light source substrate 50 according to the first embodiment will be subsequently described with reference to FIGS. 1 and 2. The LED light source substrate 50 includes an LED-mounted substrate 53 having a circuit board and the LED bare chips 52 and a high refractive index layer 58 having an embedding layer 56 and a base material layer 57. These components will be sequentially described below.

As the circuit board 51, a general circuit board using glass epoxy, polyimide, or aluminum as a base material can be used. As shown in FIG. 2, a wiring circuit is formed on the circuit board 51, and electrode pads 54 for mounting the LED bare chips 52 are provided on the circuit board 51 at predetermined intervals. The LED bare chips 52 electrically connected to wiring circuit via the electrode pads 54 and are also connected to a power supply via cables or the like. The wiring circuit is preferably formed to enable to control and apply a current from the power supply to each LED bare chip 52. Each electrode pad 54 is preferably painted white to improve light reflectance. For example, a white resist “PSR-4000” available from TAIYO INK MFG. CO., LTD. can be used for painting.

The LED light source substrate 50 according to the first embodiment uses the unpackaged LED bare chips 52 as light sources. As the LED bare chips 52, general LED bare chips can be used. Each LED bare chip 52 has a very small outer shape with a bottom surface area of 0.1 mm×0.2 mm and a height (mounting height H₅₂) of about 0.1 mm. The LED bare chip 52 is a bare chip, and hence its emission color is monochromatic. The LED bare chips 52 typically emit blue light. However, three types of LED bare chips that respectively emit red light, green light, and blue light may be arranged side by side. LED bare chips are roughly classified into face-up type bare chips having electrodes on the opposite side to the surface connected to the circuit board and flip-chip type bare ships having electrodes on the connecting surface side. The first embodiment preferably uses flip-chip type LED bare chips 52. When face-up type LED bare chips are used, for example, wires are used to electrically connect them to the circuit board (wire bonding). As will be described later, it is preferable to use flip-chip type LED bare chips because when the high refractive index layer 58 is provided to embed face-up type LED bare chips, air bubbles enter the layer because of the interference of wires, or disconnection of wires and their contact with other portions cause troubles. The arrangement of each LED bare chip 52 is not specifically limited. As shown in FIG. 2, the first embodiment uses a flip-chip type LED bare chip having a light-emitting layer 52P formed by stacking GaN with a refractive index of about 2.3 or AlInGaP with a refractive index of about 3.3 on a sapphire substrate 525 with a refractive index of about 1.75. Each flip-chip type LED bare chip 52 has an electrode 52E disposed on the opposite surface of the light-emitting layer 52P to the sapphire substrate 52S, and hence the surface of the electrode 52E can be directly connected to the electrode pad 54 formed on the circuit board with a solder 55 (flip-chip mounting). Note that the electrode 52E of the LED bare chip 52 may be connected to the electrode pad 54 with a gold bump or the like instead of the solder 55. The surface of the LED-mounted substrate 53 to which the LED bare chips 52 are connected will be sometimes referred to as a mounting surface 53S hereinafter.

The high refractive index layer 58 is disposed on the mounting surface 53S of the LED light source substrate 50 according to the first embodiment astride the LED bare chips so as to embed them. In this case, “to embed” is to dispose the high refractive index layer 58 so as to cover the side surfaces, the upper surface, and the like of the surfaces of the LED bare chips 52 except for the surfaces connected to the circuit board 51. As will be described in more detail later, the high refractive index layer 58 can be provided on the LED-mounted substrate 53 by bonding, to the mounting surface 53S, a one-sided adhesive sheet 70 prepared by providing an adhesive resin layer 72 forming the embedding layer 56 on one surface of a base material 71 forming the base material layer 57.

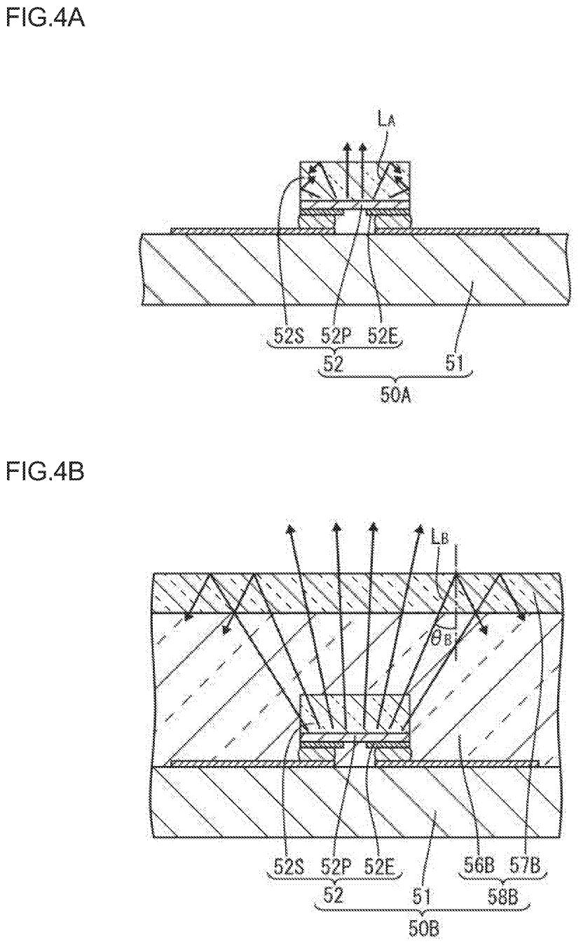

The high refractive index layer 58 is preferably formed from a resin or the like having light transmissivity and a high refractive index n. As described above, this is because each LED bare chip 52 is formed from materials each having a high refractive index, and hence the high refractive index layer 58 is formed from a material having as high a refractive index as possible to reduce the difference in refractive index from each constituent material of the LED bare chip 52, thereby achieving a high light exiting ratio from the LED bare chip 52 to the high refractive index layer 58. Note that when the high refractive index layer 58 has higher refractive index than each constituent material of the LED bare chip 52, total reflection does not occur at the interfaces between them. Forming the high refractive index layer 58 to have a refractive index higher than at least the refractive index 1 of air will achieve a high light exiting ratio from the LED bare chip 52 as compared with an LED light source substrate 50A having the LED bare chip 52 mounted on the circuit board 51 in a bare state, as will be described later with reference to FIG. 4A.

As in the first embodiment, when the high refractive index layer 58 has a multilayer structure, the layer disposed in contact with the LED bare chip 52 so as to embed it, in particular, that is, the embedding layer 56, is preferably formed to have the refractive index n close to that of each constituent material of the LED bare chip 52. More specifically, when the LED bare chip 52 includes the sapphire substrate 52S, the embedding layer 56 is preferably formed to have the refractive index n higher than the refractive index 1.75 of the sapphire substrate 525 (n>1.75). This is because this make all light exit from the interface between the sapphire substrate 52S and the embedding layer 56. Note that because the LED bare chip 52 includes the light-emitting layer 52P made of GaN or AlInGaP having a higher refractive index than the sapphire substrate 52S, forming the embedding layer 56 to make it nave the refractive index n higher than 1.75 will further increase the light exiting ratio at the interface between the light-emitting layer 52P and the embedding layer 56. In practice, however, because the light-emitting layer 52P is much thinner than the sapphire substrate 52S, the effect of improving the light exiting ratio from the LED bare chip 52, which is obtained by increasing the refractive index within a range exceeding 1.75, is only limited. Note that the base material layer 57 disposed on the opposite side of the embedding layer to the LED-mounted substrate 53 in the high refractive index layer 58 is also preferably formed from a resin or the like having a high refractive index close to that of the embedding layer 56 in terms of improving the light exiting ratio from the embedding layer 56 to the base material layer 57.

Among the layers constituting the high refractive index layer 58, the embedding layer 56 that embeds the LED bare chips 52 is preferably formed from an adhesive material, for example, a soft adhesive resin. This is because forming the embedding layer 56 by using such a material can easily bring the embedding layer 56 into tight contact with the LED bare chips 52. As described above, because each LED bare chip 52 has a very small bottom surface area and the area of the portion connected to the circuit board 51 with the solder 55 or the like is small, an impact or the like may cause the LED bare chip 52 to peel off the circuit board 51. However, embedding the LED bare chip 52 in the embedding layer 56 while the embedding layer 56 is in tight contact with the LED bare chip 52 makes it difficult to cause a trouble due to dropping or disconnection of the LED bare chip 52.

The embedding layer 56 is preferably formed from a resin or the like having higher light transmissivity. This is because forming a layer having higher light transmissivity as the embedding layer 56 makes it possible to propagate light emitted from the LED bare chip 52 to a distant position. It is not preferable that light diffusing particles or the like made of TiO₂ are mixed in the embedding layer 56. This is because light incident from the LED bare chip 52 onto the embedding layer 56 is scattered near the LED bare chip 52 and enters the LED bare chip 52 again or strikes and is absorbed by a structure with a low reflectance, such as the electrode pad 54 formed on the circuit board 51 or the solder 55 that connects the LED bare chip 52 to the electrode pad 54, although it depends on the particle size or density of the particles. More specifically, for example, the embedding layer 56 preferably has a haze of 30% or less.

The embedding layer 56 is also preferably formed from a resin or the like having excellent heat resistance. This is is because the LED bare chip 52 generates high temperature when being turned on, and hence using a material forming the embedding layer 56 which changes in color or deteriorates due to heat causes a deterioration in the light use efficiency of the LED light source substrate 50 and makes it impossible to ensure durability of the LED light source substrate 50.

In consideration of the respective conditions described above, operability, cost, and the like, the embedding layer 56 is much preferably formed from a silicone-based adhesive resin (an example of an adhesive material having a refractive index of about 1.41. This is because a silicone-based adhesive resin has high light transmissivity and heat resistance and is resistant to color change due to heat, although having a slightly low refractive index. In addition, an acrylic-based adhesive resin having a refractive index of about 1.49 can be preferably used. This is because an acrylic-based adhesive resin has very high light transmissivity, although having heat resistance lower than that of a silicone-based adhesive resin. It is also possible to use an epoxy-based or urethane-based adhesive resin. It is especially preferable to uniformly disperse metallic oxide nano-particles with high refractive index, such as TiO₂ or ZrO₂ in these resins as bases, or introduce sulfur with a high atomic reflectance in a polymer into a polymer in terms of greatly improving the refractive index and greatly improving light use efficiency without decreasing the light transmissivity of the embedding layer 56.

The embedding 56 is preferably formed to have a uniform thickness. This is because this makes it easy to bring the embedding layer 56 into tight contact with the LED bare chips 52 without any gaps from the surroundings of the LED bare chips 52 to cover the entire surface except for the connecting surfaces between the LED bare chips 52 and the circuit board 51. More specifically, as shown in FIG. 2, the embedding layer 56 is preferably formed to have a thickness T₅₆ in a range from 1 to 2 times of a mounting height H₅₂ the LED bare chip 52 (H₅₂≤T₅₆≤2H₅₂). Assume that the thickness T₅₆ is equal to or more than the mounting height H₅₂. In this case, when the high refractive index layer 58 is provided upon bonding of the one-sided adhesive sheet 70, even if air bubbles are slightly left around the LED bare chip, 52 upon bonding of the one-sided adhesive sheet 70, the air bubbles can be removed by an autoclave treatment under proper conditions. If the thickness T₅₆ is smaller than the mounting height H₅₂, air bubbles are left even after the execution of an autoclave treatment. This makes it difficult to bring the embedding layer 56 into tight contact with the LED bare chips 52. Using the one-sided adhesive sheet 70 having the adhesive resin layer 72 formed to have the thickness T₅₆ equal to or less than 2 times the mounting height H₅₂ makes it possible to provide the high refractive index layer 58 to have convex portions 58P on the surface by using a simple method pressure-bonding the one-sided adhesive sheet 70 onto the mounting surface 53S. Forming the adhesive resin layer 72 with the thickness T₅₆ larger than 2 times the mounting height H₅₂ makes it difficult to cause the one-sided adhesive sheet 70 to deform along the outer shapes of the LED bare chips 52. As a consequence, the intended convex portions 58P are not sometimes formed on the high refractive index layer 58. More specifically, as described above, in the first embodiment using the LED bare chips 52 each having the mounting height H₅₂ of about 0.1 mm, the embedding layer 56 (adhesive resin layer 72) is preferably formed such that the thickness T₅₆ becomes, for example, about 0.15 mm.

Among the layers constituting the high refractive index layer 58, the base material layer 57 disposed on the opposite side of the embedding layer 56 to the LED-mounted substrate 53 is preferably formed from a non-adhesive sheet or film so as to function as a support having shape retention. This is because when the high refractive index layer 58 is provided upon pressure-bonding of the one-sided adhesive sheet 70, the base material 71 makes the one-sided adhesive sheet 70 retain its shape, thus facilitating work. The base material layer 57 preferably has a predetermined surface hardness or more. This is because in the LED light source substrate 50, the surface of the soft embedding layer embedding the LED bare chips 52 is covered by the base material layer 57 described above to protect the embedding layer 56 and the LED bare chips 52, thus improving durability. In consideration of such conditions described above, the base material layer 57 is preferably formed from a PET film or the like.

As shown in FIG. 2 and the like, the thickness T₅₇ of the base material layer 57 is substantially constant. The thickness T₅₇ is preferably in a range from 7 μm to 500 μm, more preferably from 10 μm to 300 μm, and especially preferably from 12 μm to 200 μm. This is because making the thickness T₅₇ fall within such ranges will facilitate work when providing he high refractive index layer 58 upon pressure-bonding of the one-sided adhesive sheet 70. If the thickness T₅₇ is smaller than the above range, because the shape retention strength of the base material 71 as a support, which constitutes the one-sided adhesive sheet 70, is not sufficient, creases are sometimes formed on the one-sided adhesive sheet 70 at the time of the formation of an adhesive layer. In contrast to this, if the thickness T₅₇ is larger than the above range, because the shape retention strength of the base material 71 excessively increases, the one-sided adhesive sheet 70 does not deform along the outer shapes of the LED bare chips 52, resulting in difficulty in forming the convex portions 58P on the high refractive index layer 58. This suppresses the effect of improving light use efficiency.

As shown in FIG. 1 and the like, the high refractive index layer 58 is formed to have the convex portions 58P protruding to the opposite side to the circuit board 51 at the positions at which the LED bare chips 52 are embedded. In other words, the convex portions 58P are formed on the high refractive index layer 58 by causing the high refractive index layer 58 to protrude to the opposite side to the circuit board 51 at the positions at which the LED bare chips 52 are embedded with reference to the height of the high refractive index layer 58 from the circuit board 51 at the position where the LED bare chip 52 is not embedded. The surface of each convex portion 58P preferably has a shape conforming to the outer shape of a corresponding one of the LED bare chips 52. In this case, “a shape conforming to the outer shape” not limited to the surface of each convex portion 58P which is similar to the outer shape of a corresponding portion of a corresponding one of the LED bare chips 52, and includes a shape formed such that the distance from the LED bare chip 52 to the surface of the convex portion 58P falls within a predetermined range (for example, in the range in which the difference between the maximum value of the distance and the minimum value of the distance fails within 30% of the maximum value). When, for example, each LED bare chip 52 has a rectangular parallelepiped outer shape, the convex portion 58P may be constituted by curved surfaces formed to almost conform to the respective planes constituting the outer shape. More specially the surface of each convex portion 58P can have, for example, a hemispherical shape, polygonal column shape, columnar shape, polygonal cone shape, or circular cone shape. In view of improving the light exiting ratio, as shown in FIG. 2, it is especially preferable that the surface of the convex portion 58P is formed to have a substantially hemispherical shape (convex lens shape). This is because forming each convex portion 58P in this manner makes it possible to greatly improve the light exiting ratio from the high refractive index layer 58 as compared with a case in which the surface of the high refractive index layer 58 is formed to have flat shape. When the high refractive index layer 58 is provided upon pressure-bonding of the one-sided adhesive sheet 70 having the adhesive resin layer 72 with a substantially uniform thickness, a protrusion height H_{58P} of the convex portion 58P, formed at the position at which the LED bare chip 52 is embedded, from the surface of the high refractive index layer 58 at the position where the LED bare chip 52 is not embedded is equal to the mounting height H₅₂ of the LED bare chip 52 (H_{58P}=H₅₂). In this case, “is equal” includes not only a case in which the protrusion height is perfectly equal to the mounting height but also a case in which they can be regarded as substantially equal. For example, when the base material layer 57 and the embedding layer 56 are provided upon bonding of the one-sided adhesive sheet 70, each convex portion 58P can include errors due to unintentional fluctuations in the thickness of the adhesive resin layer 72 provided on the base material 71 of the one-sided adhesive sheet 70, the deformation of the adhesive resin layer 72 at the time of pressure-bonding of the one-sided adhesive sheet 70, and the like. Such function effects of the convex portion 58P will be described later.

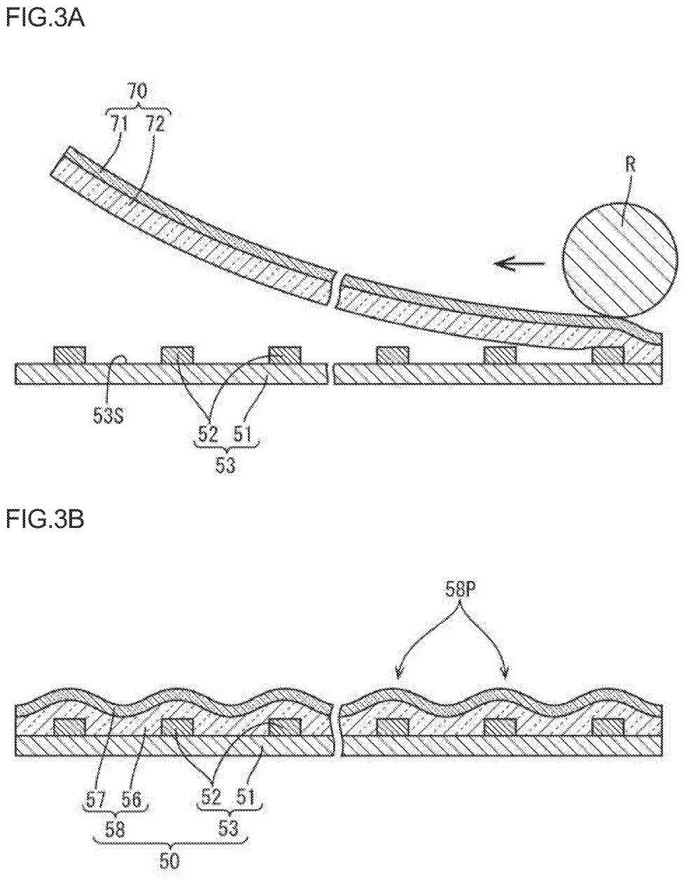

An example of a method of producing the LED light source substrate 50 having the above structure will be subsequently described with reference to FIGS. 3A and 3B. An example of a method of providing the embedding layer 56 and the base material layer 57 will be described below. Before provision of the embedding layer 56 and the base material layer 57, the LED-mounted substrate 53 is prepared by mounting the LED bare chips 52 on the circuit board 51 on which wiring routes are formed (LED bare chip mounting step). Note that a flip-chip type chip is preferably used as the LED bare chip 52, which is preferably directly connected to the electrode pad 54 of the circuit board 51 with the solder 55.

The one-sided adhesive sheet 70 is prepared differently from the LED-mounted substrate 53. The one-sided adhesive sheet 70 can be prepared by forming the adhesive resin layer 72 on one surface of the base material 71, formed from, for example, non-adhesive PET film having light transmissivity, by lying a silicone-based adhesive resin with a substantially uniform thickness. The one-sided adhesive sheet 70 disposed such that the adhesive resin 72 is located on the lower side (beside the LED-mounted substrate 53) on the mounting surface 53S of the LED-mounted substrate 53. As shown FIG. 3A, the surface of the one-sided adhesive sheet 70 which is located beside the base material pressed with a roller R to pressure-bond the one-sided adhesive sheet 70 so as to seal between the LED bare chips 52 with adhesive resin while pushing air by deforming the adhesive resin layer 72. The pressure and speed at the time pressure bonding are preferably adjusted in accordance with the adhesion resin forming the adhesive resin layer 72, the properties of the base material 71, and the like. When air bubbles are left between the adhesive resin layer 72 and the LED bare 52 or the mounting surface 53S, the air bubbles can be removed performing an autoclave treatment under proper conditions. Conditions for an autoclave treatment can be, for example, 45° C., 0.5 and 20 min. With third process, the high refractive index layer 58 is provided on the mounting surface 53S of the LED-mounted substrate 53 astride the LED bare chips 52 so as to embed them (LED bare chip embedding step).

In the above LED bare chip embedding step, preparing the one-sided adhesive sheet 70 by adjusting the adhesive resin layer 72 and the base material 71 so as to form the embedding layer 56 and the base material layer 57 described above makes it possible to pressure-bond the one-sided adhesive sheet 70 onto the mounting surface 53S of the LED-mounted substrate 53 while causing the one-sided adhesive sheet 70 to deform in conformity with the outer shape of each LED bare chip 52. As shown in FIG. 3B, this produces the LED light source substrate 50 including the high refractive index layer 58 having the convex portions 55P protruding to the opposite side of each of the LED bare chips 52 as the center to the circuit board 51.

The function effect of each convex portion 58E formed in the above manner will be subsequently described with reference to FIG. 2 and FIGS. 4A and 4B. FIG. 4A schematically shows outlines of optical paths of light exiting from the light-emitting layer 52P in the LED light source substrate 50A mounted on the circuit board 51 while the LED bare chip 52 is in a bare state. In the LED light source substrate 50A, because there is a large refractive index difference between the LED bare chip 52 formed from a high refractive index material and air around the LED bare chip 52, the critical angle at the interface is very small. Accordingly, light exiting from the LED bare chip 52 is also limited to, for example, light exiting in a direction substantially perpendicular to the interface at the center of the LED bare chip 52, and most of light L_{A} in the sapphire substrate 52S is reflected and confined in the interface and does not exit. As a result, in the LED light source substrate 50A, the light exiting ratio from the LED bare chip 52 is very low, resulting in a very low light use efficiency.

FIG. 4B shows how light exits from an LED light source substrate 50B with the surface of a high refractive index layer 58B embedding the LED bare chips 52 being formed into a substantially flat shape. In the LED light source substrate 50B, because the high refractive index layer 58B formed from an embedding layer 56B and a base material layer 57B each having a higher refractive index than air is disposed around the LED bare chips 52, the critical angle at the interface between each LED bare chip 52 and the high refractive index layer 58B increases. Accordingly, the ratio of light reflected by this interface is smaller than that in the LED light source substrate 50A, and the light exiting ratio from the LED bare chip 52 increases. However, in the LED light source substrate 50B, because the surface of the high refractive index layer 58B, that is, the interface between the high refractive index layer 58B and air, is formed into a substantially flat shape, light exiting in a radial state from the LED bare chip 52 enters the interface between the high refractive index layer 58B and air at a larger incident angle (the angle defined by the incident direction of light on the interface and a normal to the interface) with an increase in distance from a position immediately above the center of the LED bare chip 52. Light L_{B} entering the interface between the high refractive index layer 58B and air at an incident angle θ_{B} larger the critical angle is reflected by the interface and does not exit into air, and hence the light exiting ratio from the high refractive index layer 58B is restricted. As a result, the effect of improving the light use efficiency in the LED light source substrate 50B is limited.

The LED light source substrate 50 according to the first embodiment shown in FIG. 2 can greatly improve the light use efficiency as compared with LED light source substrates 50A and 50B described above. In the LED light source substrate 50, the high refractive index layer 58 includes the convex portions 58P, and the surface of the high refractive index layer 58, that is, the interface between the high refractive index layer 58 and air, is formed to protrude at the position at which each LED bare chip 52 is embedded. Light exiting in a radial state from each LED bare chip 52 also enters the interface between the high refractive index layer 58 and air at a relatively small incident angle at a position spaced apart from a position immediately above the center of the LED bare chip 52. The ratio of light L entering at an incident angle e smaller than the critical angle on the interface between the high refractive index layer 58 and air increases, thereby greatly improving the light exiting ratio from the high refractive index layer 58. As a result, both the light exiting ratio from the LED bare chip 52 and the light exiting ratio from the high refractive index layer 58 increase, thereby obtaining the LED light source substrate 50 with excellent light use efficiency.

As described above, the LED light source substrate according to the first embodiment includes the circuit board 51 on which a wiring circuit is formed, the LED bare chips 52 mounted on the circuit board 51, and the high refractive index layer 58 made of a material having light transmissivity and a refractive index higher than 1. The high refractive index layer 58 is disposed astride the LED bare chips 52 so as to embed the LED bare chips. The high refractive index layer 58 is formed to have the convex portions 58P protruding to the opposite side to the circuit board 51 at the positions at which the LED bare chips 52.

According to the above configuration, embedding the LED bare chips 52 in the high refractive index layer 58 (more specifically, the embedding layer 56) having a higher refractive index than air (refractive index 1) increases the light exiting ratio from each LED bare chip 52 as compared with the LED light source substrate 50A or the like having the LED bare chips 52 arranged in a bare state in air. In this case, because the high refractive index layer 58 has the convex portions 58P protruding at the positions at which the respective LED bare chips 52 are embedded, the ratio of the light L, of light propagating in the high refractive index layer 58, which enters the interface with air or the like at the small incident angle θ increases, and the light exiting ratio from the high refractive index layer 58 greatly improves. This increases both the light exiting ratio from each LED bare chip 52 and the light exiting ratio from the high refractive index layer 58, thus obtaining the LED light source substrate 50 with excellent light use efficiency. In general, because each LED bare chip 52 is very small and has a small area connected to the circuit board 51 with the solder 55 or the like, an impact or the like may cause the LED bare chip 52 to peel off the circuit board 51. However, according to the above configuration, embedding the LED bare chip 52 in the high refractive index layer 58 makes it difficult to cause dropping or disconnection of the LED bare chip 52.

In the LED light source substrate 50 according to the first embodiment, the surface of each convex portion 58P conforms to the outer shape of a corresponding one of the LED bare chips 52. With this configuration, at least the surface of each convex portion 58P, the interface between the high refractive index layer 58 and air has a shape conforming to a corresponding one of the LED bare chips 52. This can effectively increase the ratio of the light L, of light propagating in the high refractive index layer 58, which enters the interface with air or the like at the small incident angle θ. This makes it possible to effectively improve the light exiting ratio at the interface, eventually the light use efficiency in the LED light source substrate 50.

In the LED light source substrate 50 according to the first embodiment, the LED bare chips 52 are flip-chip mounted on the circuit board 51, and the high refractive index layer 58 is made of an adhesive material (for example, a silicone-based adhesive resin) and includes the embedding layer 56 that embeds the LED bare chips 52 and the base material layer 57 made of a non-adhesive material (for example, a PET film) and disposed on the opposite side of the embedding layer 56 to the circuit board 51. According to this configuration, the surface of the relatively soft adhesive embedding layer 56 embedding the LED bare chips 52 is covered by the non-adhesive base material layer 57 to protect the embedding layer 56 and the LED bare chips 52, thereby improving the durability of the LED light source substrate 50. The LED light source substrate 50 having this configuration can be easily produced bonding the so-called one-sided adhesive sheet 70 onto the circuit board 51 on which the LED bare chips 52 are mounted. The LED light source substrate 50 including the embedding layer 56 having the convex portions 58P protruding to the opposite side to the circuit board 51 at the positions at which the LED bare chips 52 are embedded and the base material layer 57 disposed on the surface of the embedding layer 56 is obtained by, for example, disposing the one-sided adhesive sheet 70 having the adhesive resin layer 72 provided on one surface of the base material 71 on the mounting surface 53S of the LED-mounted substrate 53 having the LED bare chips 52 mounted on the circuit board 51 and pressure-bonding the one-sided adhesive sheet 70 to the mounting surface 53S with the roller R or the like to seal between the LED bare chips 52 with an adhesive resin while pushing out air. In this case, directly connecting the LED bare chips 52 to the circuit board 51 with the solder 55 or the like by using flip-chip type chips as the LED bare chips having the electrodes 52E on the lower surfaces can prevent the connecting structures of the LED bare chips 52 from being damaged.

In the LED light source substrate 50 according to the first embodiment, the thickness of the base material layer 57 is in a range from 7 μm to 500 μm. According to this configuration, when the LED light source substrate 50 is produced by using the one-sided adhesive sheet 70 described above, letting the base material 71 have appropriate shape retention strength can facilitate production and bonding work of the one-sided adhesive sheet 70. In this manner, the LED light source substrate 50 with stable quality can be easily produced.

In the LED light source substrate 50 according to the first embodiment, the thickness of the embedding layer 56 is in a range from 1 to 2 times of the mounting height H₅₂ of each LED bare chips 52. This configuration makes it easy to bring the embedding layer 56 into tight contact with the surroundings of the LED bare chips 52 and causes the one-sided adhesive sheet 70 to deform in conformity with the outer shapes of the LED bare chips 52 when producing the LED light source substrate 50 by using the one-sided adhesive sheet 70 described above. In this manner, the convex portions 58P can be easily formed.

In the LED light source substrate 50 according to the first embodiment, the protrusion height H_{58P} of the convex portion 58P from the surface of the high refractive index layer 58 at the position where the LED bare chip 52 is not embedded is equal to the mounting height H₅₂ of the LED bare chip 52. This configuration effectively increases the ratio of the light L entering the interface between the convex portion 58P and air or the like at the small incident angle θ, thus improving the light exiting ratio. In addition, using, for example, the one-sided adhesive sheet 70 described above, which has the adhesive resin layer 72 with a substantially uniform thickness on the base material 71, makes it possible to easily produce the LED light source substrate 50.

The backlight device (lighting device) 3 according to the first embodiment includes the LED light source substrate 50 described above. This configuration can obtain the backlight device 3 with high light use efficiency.

A method of producing the LED light source substrate 50 according to the first embodiment includes an LED bare chip mounting step of preparing the LED-mounted substrate 53 by mounting the LED bare chips 52 on the circuit board 51 on which wiring routes are formed and an LED bare chip embedding step of providing the high refractive index layer 58 on the mounting surface 53S of the LED-mounted substrate 53 astride the LED bare chips 52 so as to embed the LED bare chips. The high refractive index layer 58 is made of a material having light transmissivity and a refractive index higher than 1 and is provided to have the convex portion 58P protruding to the opposite side of each of the LED bare chips 52 as the center to the circuit board 51. This configuration can produce the LED light source substrate 50 with high sight use efficiency.

In the method of producing the display device 1 according to this embodiment, the surface of each convex portion 58P conforms to the outer shape of a corresponding one of the LED bare chips 52. This configuration can effectively increase the ratio of the light L entering the interface between the high refractive index layer 58 and air or the like at the small incident angle θ, thus improving the light use efficiency in the LED light source substrate 50.

In the method of producing the display device 1 according to this embodiment, the LED bare chips 52 are flip-chip mounted on the circuit board 51, and the high refractive index layer 58 is provided by pressure-bonding the one-sided adhesive sheet 70 having the adhesive resin layer 72 made of an adhesive material (for example, a silicone-based adhesive resin) on one surface of the base material 71 made of a non-adhesive material (for example, a PET film) onto the LED-mounted substrate 53. This configuration can produce the LED light source substrate 50 with high light use efficiency by a simple process.

In the method of producing the display device 1 according to this embodiment, the thickness of the base material layer 57 formed from the base material 71 is in a range from 7 μm to 500 μm. According to this configuration, when the LED light source substrate 50 is produced by using the one-sided adhesive sheet 70 described above, letting the base material 71 have an appropriate shape retention strength makes it possible to provide the high refractive index layer having the convex portions 58P by easily performing production and bonding work of: the one-sided adhesive sheet 70. In this manner, the LED light source substrate 50 with stable quality can be easily produced.

In the method of producing the display device 1 according to this embodiment, the thickness T₅₆ of the embedding layer 56 formed from the adhesive resin layer 72 is in a range from 1 to 2 times of the mounting height H₅₂ of the LED bare chip 52 (H₅₂≤T₅₆≤2H₅₂). This configuration facilitates bringing the embedding layer 56 into tight contact with the surroundings of the LED bare chips 52 without any gaps and also facilitates causing the one-sided adhesive sheet 70 to conform to the outer shape of each LED bare chip 52 when producing the LED light source substrate 50 by using the one-sided adhesive sheet 70 described above. In this manner, the convex portions 58P can be easily formed.

In the method of producing the display device 1 according to this embodiment, the protrusion height H_{58P} of the convex portion 58 is equal to the mounting height. H₅₂ of the LED bare chip 52 (H_{58P}=H₅₂). Preparing the one-sided adhesive sheet 70 so as to make the thicknesses of the embedding layer 56 and the base material layer 57 fall within the above ranges makes it possible to stably and easily produce the LED light source substrate 50. This configuration effectively increases the ratio of the light L entering the interface between the convex portion 58P and air or the like at the small incident angle θ, thus improving the light exiting ratio. For example, using the sheet having the adhesive resin layer 72 with a substantially uniform thickness on the base material 71 as the one-sided adhesive sheet 70 described above makes it possible to produce the LED light source substrate 50.

### Second Embodiment

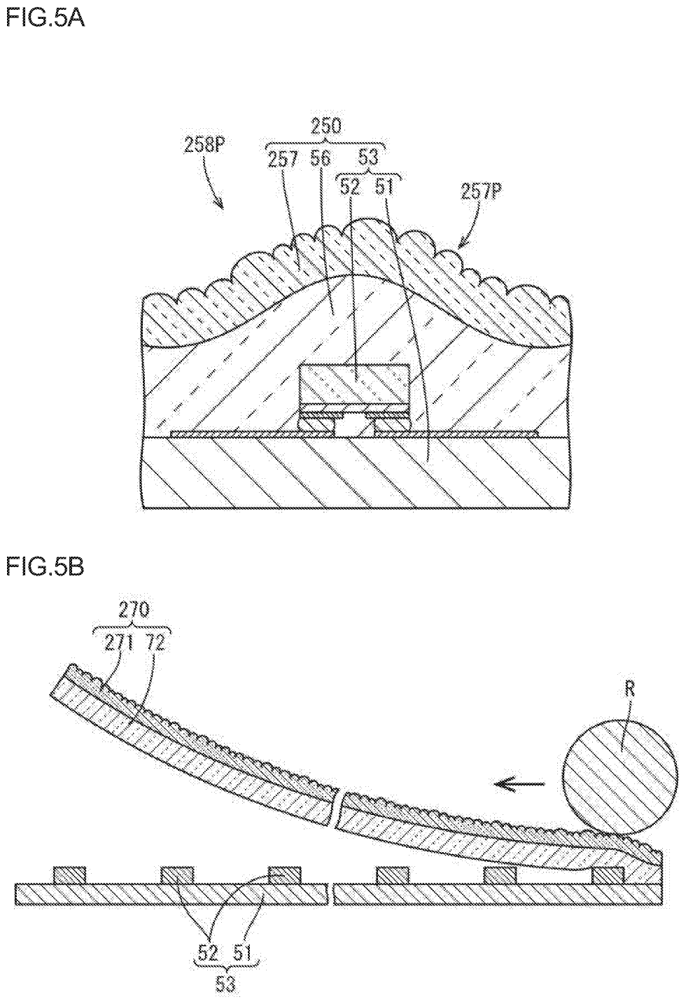

The second embodiment will be described with reference to FIGS. 5A and 5B. An LED light source substrate 250 according to the second embodiment differs from the LED light source substrate 50 according to the first embodiment in that fine concave-convex portions 257P are formed on the surface of the a high refractive index layer 258. The same reference numerals denote the same components as those in the first embodiment, and a description will be omitted (the same applies to the third and subsequent embodiments).

As shown FIG. 5A, in the LED light source substrate 250 according to the second embodiment, the fine concave-convex portions 257P are formed in a completely random state on the entire surface of a base material layer 257 constituting the high refractive index layer 258. That is, the LED light source substrate 250 is structured such that the concave-convex portions 257P finer than convex portions 258P are formed on the entire surface of the high refractive index layer 258 (more specifically, the base material layer 257) including the convex portions 258P protruding at a locations (locations where the LED bare chips 52 are embedded). FIG. 5A shows the concave-convex portions 257P each having a substantially hemispherical shape (convex lens shape). However, the concave-convex portions may be designed to refract light propagating in the high refractive index layer 258 at the designed diffusion angle, and may have, for example, a prism-like shape. As shown in FIG. 5A, when both the convex portion 258P and the concave-convex portion 257P are formed a substantially hemispherical form, for example, the concave-convex portions 257P can be formed to have a protrusion height almost equal to 1/10 to ⅓ that of the convex portion 258P. The concave-convex portions 257P may be formed after the high refractive index layer 258 is provided on an LED-mounted substrate 53. However, in consideration of work efficiency, design accuracy, cost, and the like, as shown in FIG. 5B, a one-sided adhesive sheet 270 is preferably prepared by providing an adhesive resin layer 72 on one surface of a base material 271 having the concave-convex portions 257P and bonded onto the LED-mounted substrate 53. In this case, more specifically, as the base material 271, an industrial lens diffusion plate LSD (Light Shaping Diffusers) available from Luminit LTD can be used.

In the LED light source substrate 250 according to the second embodiment, forming the fine concave-convex portions 257P on the surface of the high refractive index layer 258 (base material layer 257) increases the light exiting ratio. This enables the LED light source substrate 250 to constitute a lighting device with high light use efficiency.

### Third Embodiment

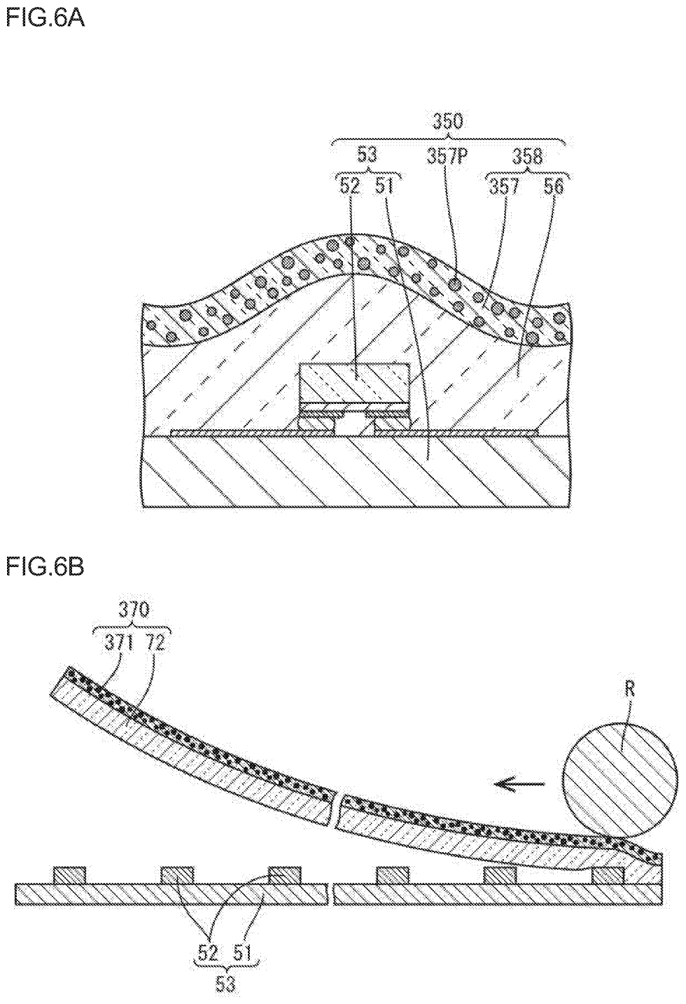

The third embodiment will be described with reference to FIGS. 6A and 6B. As shown in FIG. 6A, an LED light source substrate 350 according to the third embodiment differs from the LED light source substrate 50 according to the first embodiment in that a base material layer 357 constituting a hi refractive index layer 358 contains light diffusing particles 357P. As the light diffusing particles known particles such as light diffusing particles made of TiO₂ can be used without any limitations. As shown in FIG. 6B, the LED light source substrate 350 is preferably produced by preparing a one-sided adhesive sheet 370 having an adhesive resin layer 72 provided on one surface of a base material 371 dispersed and mixed with the light diffusing particles 357P and bonding the one-sided adhesive sheet 370 to an LED-mounted substrate 53. In this case, as the base material 371, Chemical Mat (registered trademark) available from KIMOTO Co., Ltd. can be used.

In the LED light source substrate 350 according to the third embodiment, the base material layer 357 constituting the high refractive index layer 358 contains the light diffusing particles 357P to increase the light exiting ratio. This enables the LED light source substrate 350 to constitute a lighting device with high light use efficiency.

### Fourth Embodiment

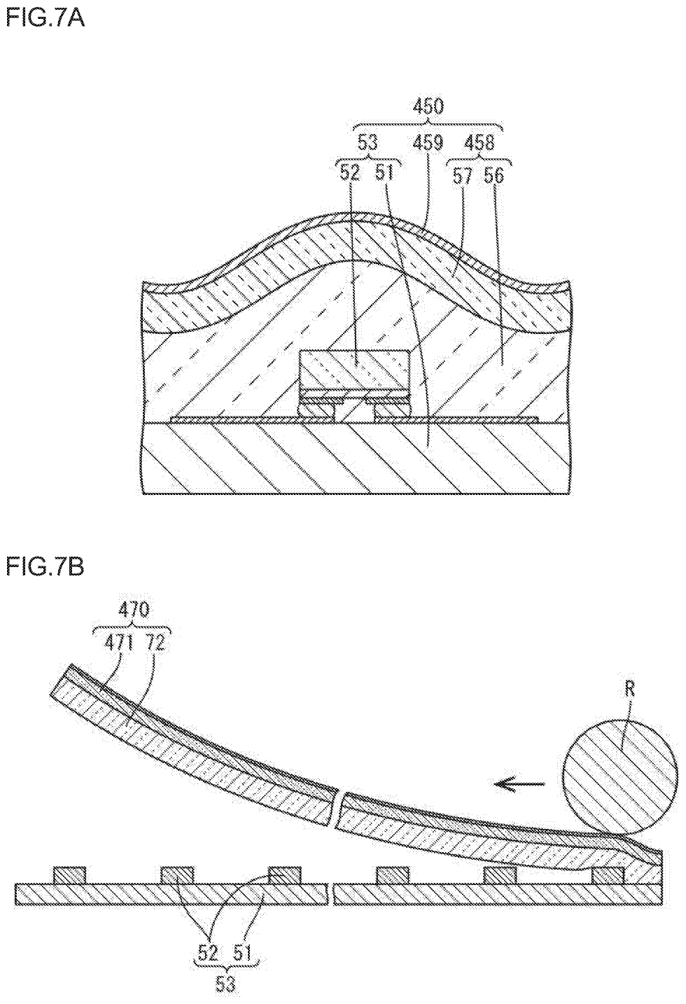

The fourth embodiment will be described with reference to FIGS. 7A and 7B. An LED light source substrate 450 according to the fourth embodiment differs from the LED light source substrate 50 according to the first embodiment in that a antireflection layer 459 that has light transmissivity and reduces the reflection of light is disposed on the surface of a high refractive index layer 458 (the surface on the opposite side to the circuit board 51). As shown in FIG. 7A, antireflection layer 459 may be provided on the surface of the base material layer 57 (the surface on the opposite side to the embedding layer 56) to cover the entire area or may be partly provided on the surface. As the antireflection layer 459, a known layer can be used without any limitations as long as it has light transmissivity and an antireflection function. For example, a low refractive index coating resin layer, metal multilayer film, or moth-eye structure can be suitably used. More specifically, the antireflection layer 459 can be formed by using, for example, OPSTAR (registered trademark) available from JSR Co., Ltd. The LED light source substrate 450 may be produced by preparing a one-sided adhesive sheet 470 having an adhesive resin layer 72 provided on one side of a base material 471 having the antireflection layer 459 and bonding the one-sided adhesive sheet 470 to an LED-mounted substrate 53. In this case, as the base material 471, AR1 or AR1.5 available from Dexerials Co., Ltd., MOSMTTE registered trademark), which is a moth-eye type high function film available from Mitsubishi Chemical Co., Ltd., or the like can be used.

In the LED light source substrate 450 according to the fourth embodiment, the antireflection layer 459 having the light transmissivity is disposed on the surface of the high refractive index layer 458 to improve the transparency of the high refractive index layer 458 by suppressing the reflection of light at the interface with air and increase the light exiting ratio. This enables the LED light source substrate 450 to constitute a lighting device with high light use efficiency. Note that using the antireflection layer 459 that has excellent rubfastness and has high surface hardness makes it possible to improve the durability of the LED light source substrate 450.

### Fifth Embodiment

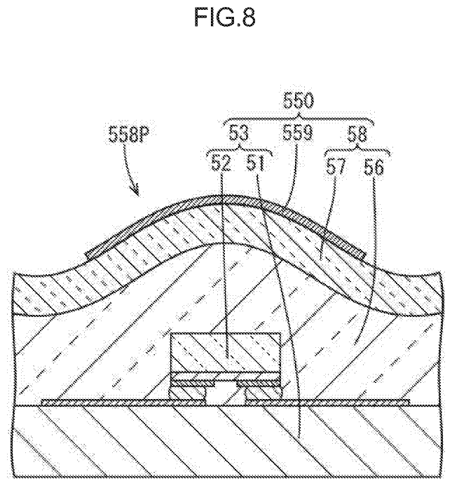

The fifth embodiment will be described with reference to FIG. 8. An LED light source substrate 550 according to the fifth embodiment differs from the LED light source substrate 50 according to the first embodiment in that light reflecting layers 559 that have light transmissivity and reflect light are disposed at the positions on a high refractive index layer 58 at which LED bare chips 52 are embedded, that is, on the surface portions at the formation positions of convex portions 558P (surface portions on the opposite side to a circuit board 51). As the light reflecting layer 559, a known layer can be used without any limitations as long as it has light transmissivity and a light reflecting function. For example, a high-reflectance thin metal film made of silver, aluminum, or an alloy of them or a white ink layer can be suitably used.

In the LED light source substrate 550 according to the fifth embodiment, the light reflecting layers 559 having the light transmissivity are arranged on the surface portions, of high refractive index layer 558, which are located at the positions where LED bare chips 52 are embedded (surface portions on the opposite side to the circuit board 51). This prevents high-density light from exiting immediately above the LED bare chips 52, thereby making light exiting from the LED bare chips 52 uniform. This enables the LED light source substrate 550 to constitute a lighting device with reduced luminance nonuniformity.

Although this technology has been described in detail above in the respective embodiments, they are merely exemplary and do not limit the scope of the claims. The technology described in scope of the claims includes various modifications and alterations of the specific examples exemplified in the respective embodiments.

1. An LED light source substrate comprising:
a circuit board on which a wiring circuit is formed;
a plurality of LED bare chips mounted on the circuit board; and
a high refractive index layer made of a material having light transmissivity and a refractive index higher than 1, wherein
the high refractive index layer is disposed astride the plurality of LED bare chips so as to embed the LED bare chips, and
the high refractive index layer has a plurality of convex portions protruding to an opposite side to the circuit board at positions at which the plurality of LED bare chips are embedded.

2. The LED light source substrate according to claim 1, wherein the convex portion has a surface with a shape conforming to an outer shape of the LED bare chip.

3. The LED light source substrate according to claim 2, wherein
the LED bare chip is flip-chip mounted on the circuit board, and
the high refractive index layer includes an embedding layer that is made of an adhesive material and embeds the plurality of LED bare chips and a base material layer that is made of a non-adhesive material and disposed on an opposite side of the embedding layer to the circuit board.

4. The LED light source substrate according to claim 3, wherein the base material layer has a thickness in a range from 7 μm to 500 μm.

5. The LED light source substrate according to claim 3, wherein the embedding layer has a thickness in a range from 1 to 2 times of a mounting height of the LED bare chip.

6. The LED light source substrate according to claim 3, wherein the base material layer contains diffusing particles that diffuse light.

7. The LED light source substrate according to claim 1, wherein the convex portion has a protrusion height equal to the mounting height of the LED bare chip, the protrusion height being a height from a surface of the high refractive index layer at a position at which the LED bare chip is not embedded.

8. The LED light source substrate according to claim 1, wherein the high refractive index layer has fine concave-convex portions on the surface.

9. The LED light source substrate according to claim 1, wherein the high refractive index layer has the surface on which a antireflection layer that has light transmissivity and reduces reflection of light is disposed.

10. The LED light source substrate according to claim 1, wherein the high refractive index layer has surface portions at the plurality of convex portions on which light reflecting layers that have light reflectivity and reflect light are arranged.

11. A lighting device comprising an LED light source substrate according to claim 1.

12. A method of producing an LED light source substrate comprising:
an LED bare chip mounting step of preparing an LED-mounted substrate by mounting a plurality of LED bare chips on a circuit board on which wiring routes are formed; and
an LED bare chip embedding step of providing a high refractive index layer on a mounting surface of the LED-mounted substrate astride the plurality of LED bare chips so as to embed the LED bare chips,
wherein the high refractive index layer is made of a material having light transmissivity and a refractive index higher than 1 and has convex portions protruding to an opposite side of each of the plurality of LED bare chips as a center to the circuit board.

13. The method of producing the LED light source substrate according to claim 12, wherein the convex portion has a surface with a shape conforming to an outer shape of the LED bare chip.

14. The method of producing the LED light source substrate according to claim 12, wherein
the LED bare chip is flip-chip mounted on the circuit board, and
the high refractive index layer is provided by pressure-bonding a one-sided adhesive sheet the LED-mounted substrate, the one-sided adhesive sheet having an adhesive resin layer made of an adhesive material on one surface of a base material made of a non-adhesive material.

15. The method of producing the LED light source substrate according to claim 14, wherein the base material forms a base material layer having a thickness in a range from 7 μm to 500 μm.

16. The method of producing the LED light source substrate according to claim 14, wherein the adhesive resin layer forms an embedding layer having a thickness in a range from 1 to 2 times of a mounting height of the LED bare chip.

17. The method of producing the LED light source substrate according to claim 12, wherein the convex portion has a protrusion height equal to the mounting height of the LED bare chip, the protrusion height being a height from a surface of the high refractive index layer at a position at the LED bare chip is not embedded.
